(19) United States
(12) Patent Application Publication
(10) Pub. No.: US 2012/0025894 A1
(43) Pub. Date: Feb. 2, 2012

(54) Multi-Mode Output Transmitter

(75) Inventors: Shih Jyun Yang, Hsinchu Hsien (TW); Chun Wen Yeh, Hsinchu Hsien (TW); Hsian-Feng Liu, Hsinchu Hsien (TW)

(73) Assignee: MStar Semiconductor, Inc., Hsinchu Hsien (TW)

(21) Appl. No.: 13/098,004

(22) Filed: Apr. 29, 2011

(30) Foreign Application Priority Data
Jul. 30, 2010 (TW) 099125413

(51) Int. Cl. H03K 17/00

(52) U.S. Cl. 327/408

(57) ABSTRACT

A multi-mode output transmitter includes a pair of driving circuits and a pair of common circuits. Each of the driving circuits includes an n-channel metal-oxide-semiconductor field-effect transistor (MOSFET), and each of the common circuits includes a p-channel MOSFET. In one transmission mode, one of the pair of common circuits and one of the pair of driving circuits complementarily conduct; and in another transmission mode, the pair of common circuits simultaneously conduct to provide termination resistors.

### CROSS REFERENCE TO RELATED PATENT APPLICATION

This patent application is based on Taiwan, R.O.C. patent application No. 099125413 filed on Jul. 30, 2010.

### FIELD OF THE INVENTION

The present invention relates to a multi-mode output transmitter, and more particularly, to an output transmitter capable of providing termination resistors by controlling a p-channel metal-oxide-semiconductor field effect transistor (MOSFET) in a transmission mode without a p-channel MOSFET current switch.

### BACKGROUND OF THE INVENTION

On top of a main control chip and a core circuit for performing chip functions, a chip comprises an input/output (I/O) circuit for exchanging signals and data with other circuits outside the chip. The I/O circuit comprises an output transmitter for transmitting driving signal of the core circuit to external circuits of the chip.

In order to correctly exchange signal/data between the chip and the external circuits, the I/O circuit and the external circuits of the chip need to conform to same electronic signal specifications and protocols. In other words, if one single chip is to function with different external circuits with different signal specifications, it is necessary that the chip configures various I/O circuits corresponding to the different signal specifications. For example, in a modern displayer interface specification, the High Definition Multimedia Interface (HDMI) and DisplayPort interface specifications apply current mode logic, and the low-voltage differential signaling (LVDS) interface specification is another type of interface specification. When a display control chip is applied to different interfaces such as the current logic specification and the LVDS type of specification, it is necessary different output transmitters are configured in the display control chip for transmitting video signals, thereby increasing cost, a configuration size and power consumption of the displayer control chip. Thus, an improved multiple mode transmitter is needed in the art which reduces operation voltage and cost of chip manufacture while improving multiple interface communication for I/O circuits.

### SUMMARY OF THE INVENTION

In order to overcome the foregoing disadvantages, a multi-mode output transmitter capable of adapting to different interface specifications via different transmission modes of the same output transmitter is provided to integrate output transmitters conforming to various types of interface specifications to one output transmitter. In an embodiment, the output transmitter provided by the present invention provides a dual-end differential output circuit (comprising a pair of complementary p-channel MOSFET and n-channel MOSFET) to an LVDS interface, enabling conduction of current to the foregoing p-channel MOSFET in order to provide a termination resistor conforming to an interface specification when the current logical interface is supported, or the output transmitter provides two single-end output circuits in another transmission mode. In addition, in embodiments of the present invention, the n-channel MOSFET are appropriately guarded to maintain normal operations, and power consumption caused by current leakage is also reduced. Further, the output transmitter is compatible to different combinations of types of central operating voltages or I/O operation voltages, i.e., for an I/O operating voltage for operating the output transmission and a central operating voltage for operating a central circuit (e.g., a pre-driver), the I/O operating voltage is larger than, equal to, or smaller than the central operating voltage.

An object of the present invention is to provide a multi-mode output transmitter comprising a pair of driving circuits, a pair of common circuits, a pair of switch circuits, and two coupling circuits. Each driving circuit comprises a driving input end and a driving output end. Each common circuit, corresponding to one of the driving circuits, comprises a control end and a common end that is coupled to a driving output end of the corresponding driving circuit. One of the two coupling circuits (so-called a first coupling circuit) is coupled to the common circuits, and the other (so-called a second coupling circuit) coupled to the driving circuits provides a current that is drained by the driving circuits.

In an embodiment, each of the driving circuit comprises an n-channel MOSFET, which has a gate coupled to the driving input end of the driving circuit, and a drain coupled to a driving output end. Each of the common circuit comprises a p-channel MOSFET, which has a gate coupled to the control end of the common circuit, and a drain coupled to the common end.

Each switch circuit, corresponding to one of the common circuits, has a switch input end and a coupling end that is coupled to the control end of the corresponding common circuit. Each switch circuit comprises at least a first switch and a second switch. The first switch is coupled between the switch input end and the coupling end of the switch circuit while the second switch is coupled between a predetermined voltage and the coupling end. The input end of each driving circuit and the input end of each switch circuit are coupled to the pre-driver. Each switch circuit comprises a third switch coupled between a second predetermined voltage and the coupling end. The third switch is conducted in a power-saving mode.

When the output transmitter operates in a first transmission mode (e.g., a mode supporting the LVDS signal interface specification), the first coupling circuit provides a current as a driving current. The first switch of the switch circuit conducts current, and the second and third circuits do not conduct current to connect the input end of the switch circuit to the control end of each common circuit, so that the switch circuits respectively receive a pair of rejection signals that are transmitted to the control ends of the common circuits. Each common circuit serving as a current switch determines whether to conduct the driving current at its common end according to a signal at its control end. Each driving circuit determines whether to conduct the driving current at its output end to the second coupling circuit according to a signal at its input end. The common circuit and the driving circuit coupled to one output end are complementary conducted, i.e., when one of them conducts, the other does not conduct. Only one of the pair of common circuits conducts, and only one of the pair of driving circuits conducts to support signal transmission configurations defined in the LVDS signal interface specification.

In contrast, when the output transmitter operates in a second transmission mode (e.g., a mode supporting the current logic interface specification), the first coupling circuit conducts the common circuits to an operating voltage. The second switch of the switch circuit, instead of the first and third switches, conducts current to a predetermined voltage that serves as a control signal. Under control of the control signal, the two common circuits are enabled to conduct current to provide a termination resistor at each of the common ends of the common circuits. Each driving circuit determines whether to conduct its output end to the second coupling circuit according to the signal of its input end, however, only one of the pair of driving circuit conducts. Such a configuration may support the signal transmission configuration defined in the current logical interface specification.

The output transmitter operates in a third transmission mode to realize an output circuit of a common purpose output interface. In such a transmission mode, the first coupling circuit provides a first resistor between a first operating voltage and the common circuits, and the second coupling circuit provides a second resistor between a second operating voltage and the driving circuits. In the transmission mode, each common circuit and the corresponding driving circuit form a single-end output circuit, so that the pair of common circuits and the pair of driving circuits provide two independent single-end output circuits. The first switch of the switch circuit conducts current, and the second and third switches do not conduct current to connect the input end of the switch circuit to the control ends of the common circuits, so that each common circuit realizes a drive high/pull-up driver. The driving circuit corresponding to each of the common circuit realizes a drive low/pull-down driver. Each common circuit determines whether to conduct its common end to the first operating voltage according to the signal at the control end, and each corresponding driving circuit determines whether conduct the output end to the second operating voltage according to the signal at its input end.

In an embodiment of the present invention, in addition to the original n-channel MOSFET, each driving circuit comprises a second n-channel MOSFET and a feedback circuit. The second n-channel MOSFET has a first end (e.g., a gate), a second end (e.g., a source), and a third end (e.g., a drain). The second end and the third end are respectively coupled to the output ends of the original n-channel MOSFET and the driving circuit. The feedback circuit coupled between the first end and the third end correspondingly adjusts a voltage at the first end according to a voltage signal at the output end of the driving circuit. For example, in an embodiment, when the voltage at the output end is over-high, the feedback circuit provides a lower voltage to the first end, so as to reduce a drain voltage of the original n-channel MOSFET via a gate-drain voltage of the second n-channel MOSFET. Accordingly, the original n-channel MOSFET is not undesirably affected by the over-high voltage at the output end to reduce the burden caused by the over-high voltage and to maintain reliable operations. In contrast, in another embodiment, when the voltage at the output end is over-low, the feedback circuit provides a compensating higher voltage to the first end, so as to appropriately increase the drain voltage of the original n-channel MOSFET via the gate-drain voltage of the second n-channel MOSFET, thereby avoiding error by entering of a triode region due to the over-low drain voltage of the original n-channel MOSFET.

In an embodiment, in addition to the original p-channel MOSFET, each common circuit further comprises a resistor coupled between the drain of the original p-channel MOSFET and the common end of the common circuit. In another embodiment, the common circuit further comprises an n-channel MOSFET having a drain and a source that are respectively coupled to either the drain or the source of the original p-channel MOSFET. The gate of the n-channel MOSFET has a bias voltage to form together with the original p-channel MOSFET for a configuration similar to a transmission gate. The configuration between the drain and the source of the original p-channel MOSFET reduces an overall resistance value. According to the foregoing two embodiments, linear degrees of termination resistors are increased when the common circuits provide termination resistors.

An I/O operating voltage of the output transmitter provided by the present invention is larger than, equal to, or smaller than a central operating voltage. In applications where the I/O operating voltage is smaller than or equal to the operating voltage, the feedback circuit of the driving circuit/the second n-channel MOSFET and the additional n-channel MOSFET facilitate to operate the output transmitter in a low I/O operating voltage. The feedback circuit/the second n-channel MOSFET avoids operating the driving circuit in error regions (e.g., the triode region) under a low operating voltage situation. Conducting degrees of the original p-channel MOSFET are also reduced due to the low I/O operating voltage thereby undesirably affecting the provided termination resistors; however, the additional n-channel MOSFET can appropriately solve such a problem.

In other embodiment, the p-channel MOSFET in each common circuit is a floating n-well p-channel MOSFET, i.e., the p-channel MOSFET has a floating bulk. To associate with such a transistor, the common circuit further comprises a control circuit coupled between the gate and the drain of the p-channel MOSFET. For example, when the operating voltage of the output transmitter terminates, the control circuit reduces a voltage difference between the gate and the drain to reduce a leakage current of the p-channel MOSFET.

The advantages and spirit related to the present invention can be further understood via the following detailed description and drawings.

### BRIEF DESCRIPTION OF THE DRAWINGS

FIG. 1 is a schematic diagram of an output transmitter in accordance with an embodiment of the present invention.

FIG. 2 is a schematic diagram of equivalent coupling circuits in FIG. 1 in different transmission modes in accordance with an embodiment of the present invention.

FIG. 3 is a schematic diagram of a common circuit of FIG. 1 in accordance with an embodiment of the present invention.

FIG. 4 is a schematic diagram of a driving circuit in FIG. 1 in accordance with an embodiment of the present invention.

FIG. 5 is a schematic diagram of a switch circuit in FIG. 1 in accordance with an embodiment of the present invention.

FIG. 6 is a schematic diagram of another coupling circuit in FIG. 1 in accordance with an embodiment of the present invention.

FIG. 7 to FIG. 9 are schematic diagrams of the output transmitter in FIG. 1 realizing different transmission modes in accordance with an embodiment of the present invention.

### DETAILED DESCRIPTION OF THE PREFERRED EMBODIMENT

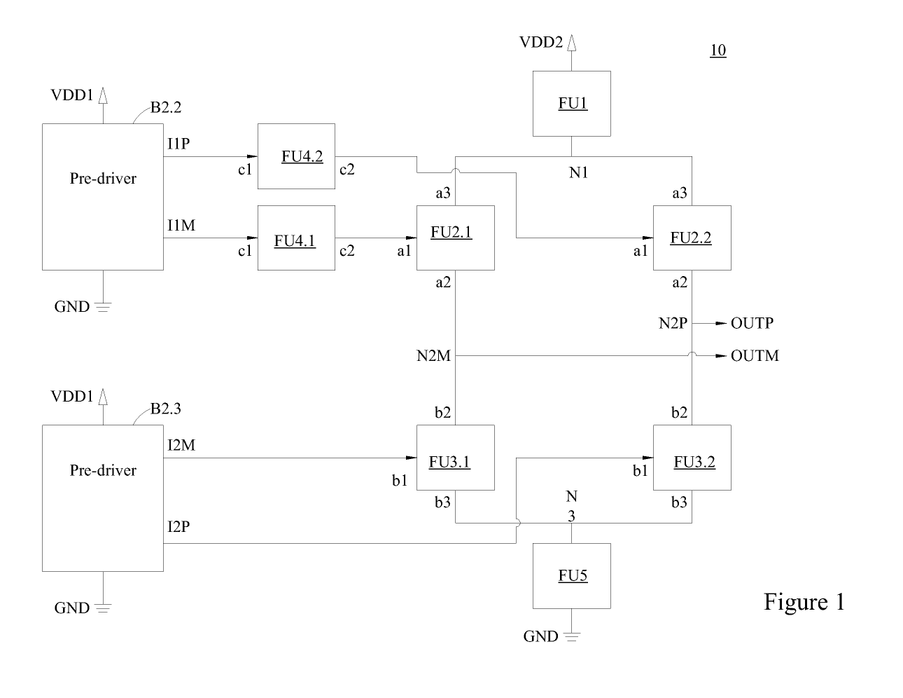

FIG. 1 shows a block diagram of circuits of an output transmitter 10 in accordance with an embodiment of the present invention. The output transmitter 10 in a chip is a structure block of a functional chip I/O circuit. For example, when core circuits (not shown) of the chip is to output a signal to external circuits outside the chip (e.g., another chip or a board, not shown in FIG. 1), the signal is transmitted to the output transmitter 10 via pre-drivers B2.2 and B2.3, and the output transmitter 10 correspondingly outputs a finalized driving signal to the external circuits. The output transmitter 10 is a multi-mode output transmitter comprising a pair of driving circuits FU3.1 and FU3.2, a pair of common circuits FU2.1 and FU2.2, a pair of switch circuits FU4.1 and FU4.2, and two coupling circuits FU1 and FU5.

In the output transmitter 10, each switch circuit FU4.1/FU4.2 respectively comprises an input end (i.e., a switch input end) c1 and a coupling end c2. The common circuit FU2.1/FU2.2 has an input control end a1, a common end a2 and a coupling end a3. The driving circuit FU3.1/FU3.2 has an input end b1 (i.e., a driving input end), an output end b2 (i.e., a driving output end), and a coupling end b3. The switch circuits FU4.1 and FU4.2 have their input ends c1 coupled to the pre-driver B2.2 for respectively receiving input signals I1M and I1P, and coupling ends c2 respectively coupled to the control ends a1 of the common circuits FU2.1 and FU2.2. The coupling ends a3 of the common circuits FU2.1 and FU2.2 are coupled to the coupling circuit FU1 at a node N1. The driving circuits FU3.1 and FU3.2 have their input ends b1 coupled to the pre-driver B2.3 for respectively receiving input signals 12M and 12P. The coupling ends b3 of the driving circuits FU3.1 and FU3.2 are coupled to the coupling circuit FU5 at a node N3.

The common circuits FU2.1 and FU2.2 respectively correspond to the driving circuits FU3.1 and FU3.2. The common end a2 of the common circuit FU2.1 is coupled to the output end b2 of the driving circuit FU3.1 at a node N2M. The common end a2 of the common circuit FU2.2 is coupled to the output end b2 of the driving circuit FU3.2 at a node N2P. The nodes N2M and N2P are respectively coupled to two output pads (not shown) of the chip. In other words, the output transmitter 10 transmits corresponding (differential) output signals OUTP and OUTM to external circuits at the nodes N2P and N2M according to the input signals I1P, I1M, 12P, and 12M of the pre-drivers B2.2 and B2.3, which operate between operating voltages VDD1 and GND. The output transmitter 10 operates between operating voltages VDD2 and GND. The operating voltage VDD1 is regarded as a core operating voltage, and the operating voltage VDD2 is regarded as an I/O operating voltage.

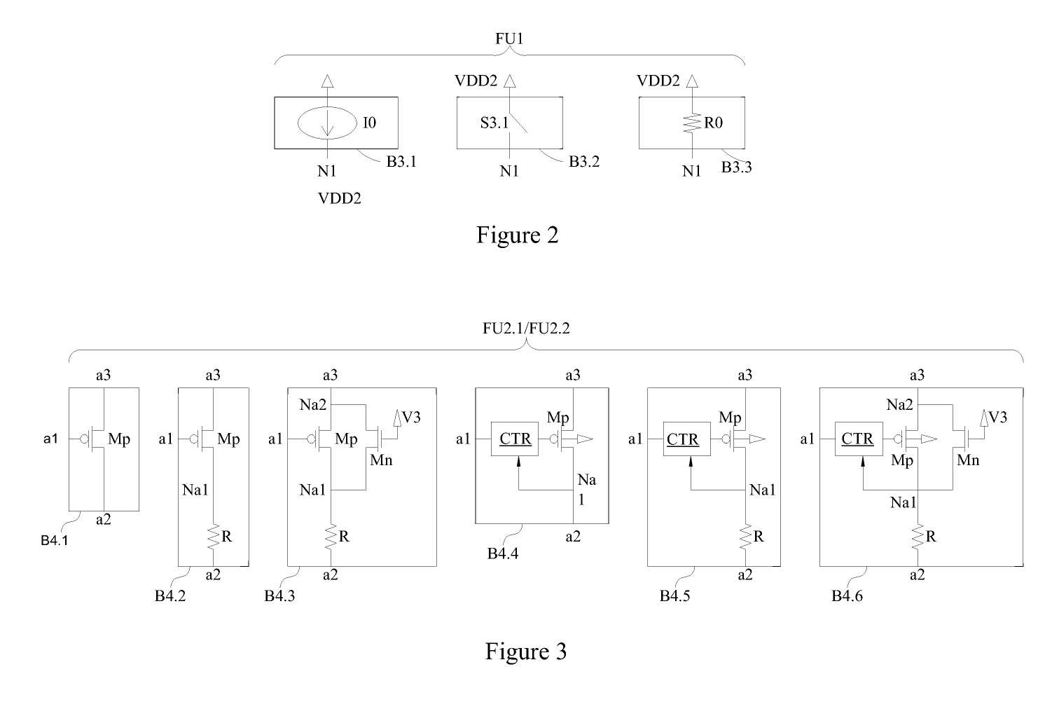

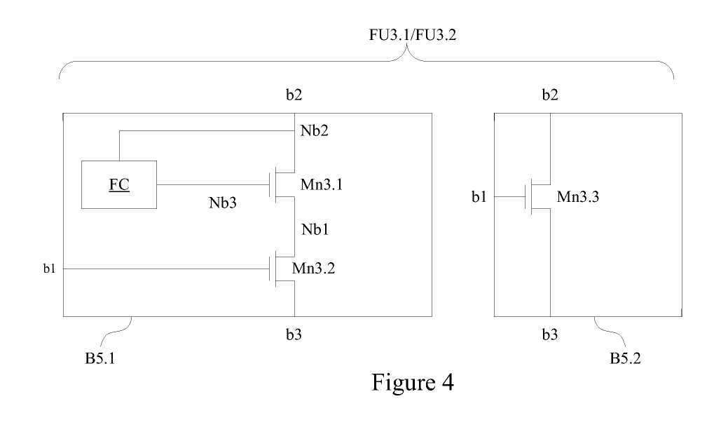

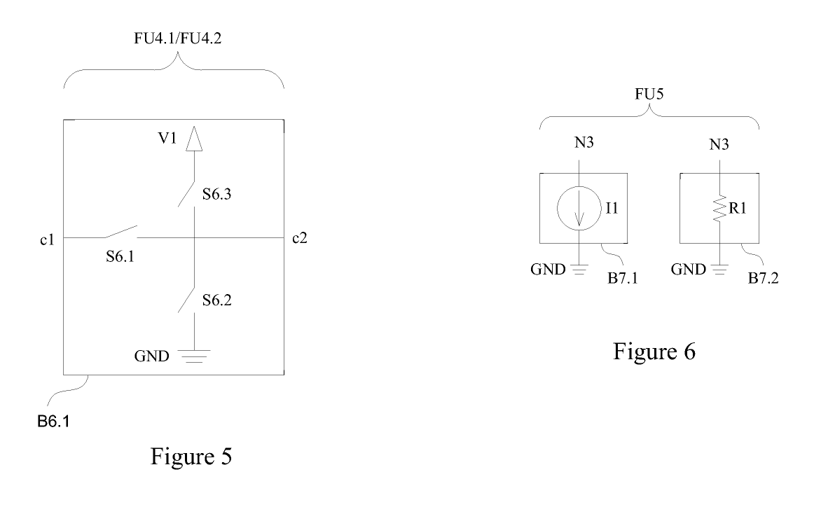

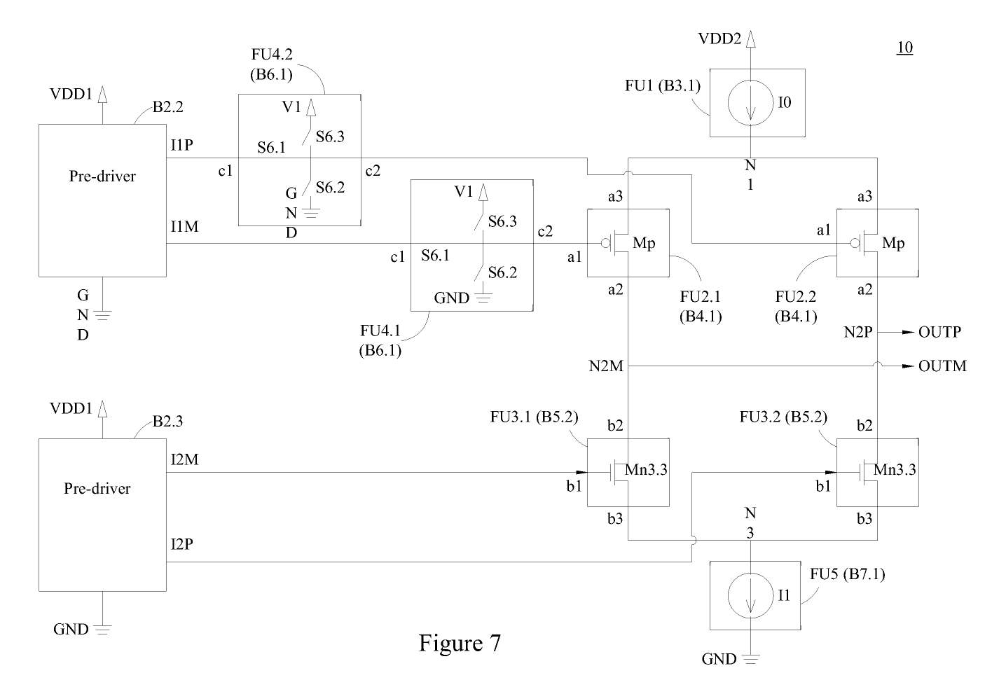

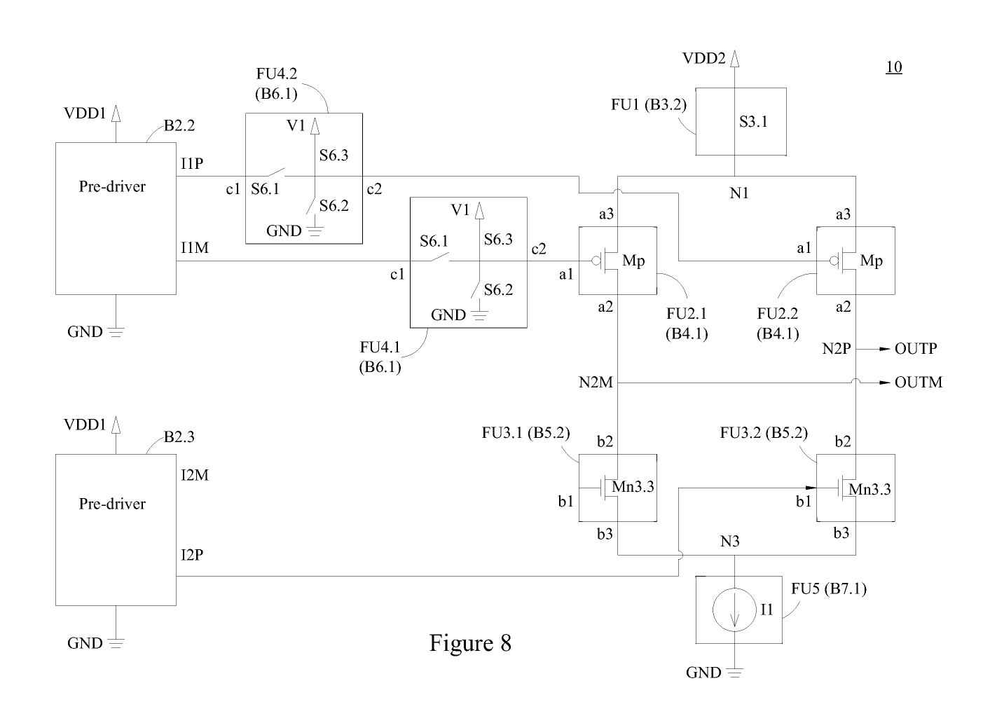

FIG. 2 to FIG. 6 illustrate more embodiments of the present invention. FIG. 2 shows a schematic diagram of equivalent coupling circuits B3.1, B3.2, and B3.3 of a coupling circuit FU1 operating in different transmission modes. FIG. 3 shows a schematic diagram of several embodiments B4.1 to B4.6 of the common circuit FU2.1/FU2.2 in accordance with the present invention. FIG. 4 shows a schematic diagram of embodiments B5.1 and B5.2 of the driving circuit FU3.1/FU3.2 in accordance with the present invention. FIG. 5 shows a schematic diagram of embodiment B6.1 of a switch circuit FU4.1/FU4.2 in accordance with the present invention. FIG. 6 shows a schematic diagram of equivalent coupling circuits B7.1 and B7.2 of the coupling circuit FU5 in different transmission modes.

In FIG. 2, the coupling circuit FU1 is equivalent to coupling circuits B3.1, B3.2 and B3.3. The coupling circuit B3.1 is a current source I0, and provides a current to a node N1. The coupling circuit B3.2 is a switch controlling the coupling of VDD2 to node N1. The coupling circuit B3.3 forms a resistor R0 between the operating voltage VDD2 and the node N1.

Referring to FIG. 3, the common circuit FU2.1 and FU2.2 are realized by one of the common circuits B4.1 to B4.6. The common circuit B4.1 comprises a transistor Mp that is a p-channel MOSFET, which has a gate coupled to the control end a1, a drain coupled to the common end a2 and a source coupled to the common end a3.

The driving circuits FU3.1 and FU3.2 are realized by one of the driving circuits B5.1 and B5.2 shown in FIG. 4. The driving circuit B5.2 comprises a transistor Mn3.3 that is an n-channel MOSFET, which has a gate coupled to the input end b1, and a drain and a source respectively coupled to the output end b2 and the coupling end b3. The driving circuit B5.1 is an enhanced version of driving circuit B5.2 and will be described with regard to an upcoming embodiment of the invention.

The switch circuits FU4.1 and FU4.2 in FIG. 1 are realized by the switch circuit B6.1 in FIG. 5. The switch circuit B6.1 comprises at least two switches S6.1 and S6.2. The switch S6.1 is coupled between the input end c1 and the coupling end c2, and the switch S6.2 is coupled between a predetermined voltage (such as the operating voltage GND) and the coupling end c2. In addition, in this embodiment, the switch circuit B6.1 selectively comprises a switch S6.3 coupled between the coupling end c2 and another predetermined voltage V1.

Referring to FIG. 6, another coupling circuit FU5 in FIG. 1 is equivalent to the coupling circuits B7.1 and B7.2 in FIG. 6. The coupling circuit B7.1 is a current source I1 that drains currents from the node N3. The coupling circuit B7.2 is equivalent to a resistor R1 between node N3 and the operating voltage GND.

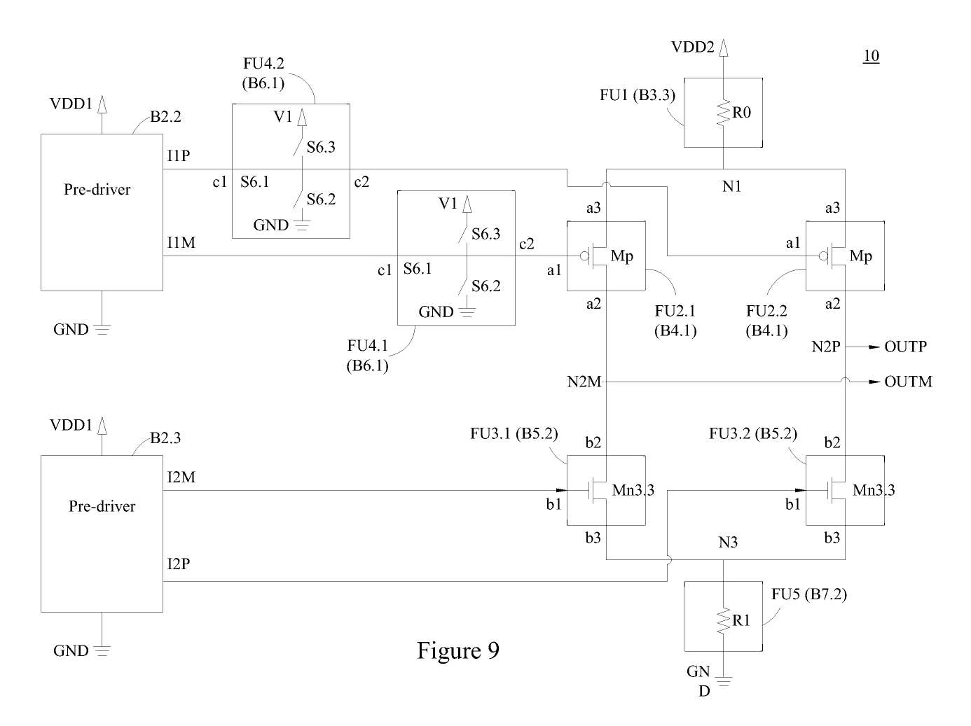

FIG. 7 shows a schematic diagram of operations of the output transmitter 10 taking the common circuit B4.1 in FIG. 3, the driving circuit B5.2 in FIG. 4, and the switch circuit B6.1 in FIG. 5 as an example. When the output transmitter 10 operates in the first transmission mode (e.g., a mode supporting the LVDS information specification), the coupling circuit FU1 is equivalent to the coupling circuit B3.1 in FIG. 2, which acts as a current source 10 providing driving current to the node N1. The coupling circuit FU5 is equivalent to the coupling circuit B7.1 in FIG. 6, which acts as a current source I1 draining currents from the node N3. In the embodiment that the switch circuits FU4.1 and FU4.2 are realized by the switch circuit B6.1, when the switch S6.1 conducts, the switches S6.2 and S6.3 turn off, so the input ends c1 of the switch circuit FU4.1 and FU4.2 respectively connect to the control ends a1 of the common circuit FU2.1 and FU2.2. At this point, the common circuits FU2.1 and FU2.2 serve as current switches to determine whether to conduct the driving current to the common ends a2 according to the input signals I1M and I1P at the control ends a1. The driving circuits FU3.1 and FU3.2 respectively determine whether to conduct the driving current at the output end b2 to the coupling circuit FU5 according to the input signals 12M and 12P at the input ends b1.

In such a mode, the input signals I1P and I1M are a pair of differential signals (or differential rejection signals), and the input signals 12M and 12P are a pair of differential rejection signals. The input signals I1P and I2M are differential signals, and the input signals 11M and 12P are differential signals. Therefore, a common circuit and a driving circuit coupled to the same output end conduct in a complementary way, i.e., only one of the pair of common circuits FU2.1 and FU2.2 conducts, and only one of the pair of driving circuits FU3.1 and FU3.2 conducts, so as to support a signal transmitter conforming to the LVDS interface specification. For example, when a transistor Mp of the common circuit FU2.1 is conducted by the input signal 11M via the switch circuit FU4.1, transistor Mp of the common circuit FU2.2 is turned off by the input signal I1P via the switch circuit FU4.2, transistor Mn3.3 of the driving circuit FU3.1 is off by the input signal 12M, and the transistor Mn3.3 of the driving circuit FU3.2 is conducted by the input signal 12P. Therefore, the driving current provided by the coupling circuit FU1 (realized as the coupling circuit B3.1) goes through common circuit FU2.1, which is connected to output to external circuits (not shown) from the node N2M. The current flows through impedance of the external circuits and back to the node N2P of the output transmitter 10, and is drained/absorbed by the coupling circuit FU5 through the conducted driving circuit FU3.2. In such a mode, the output transmitter 10 realizes a dual-end differential output circuit.

FIG. 8 shows a schematic diagram of the output transmitter 10 which operates in a second transmission mode taking the common circuit B4.1 in FIG. 3, the driving circuit B5.2 in FIG. 4, and the switch circuit B6.1 in FIG. 5, as an example. When the output transmitter 10 operates in the second transmission mode (e.g., a mode supporting the current logic interface specification), operations of the coupling circuit FU1 are equivalent to those of the coupling circuit B3.2 shown in FIG. 2. The coupling circuit FU1 is regarded as a switch S3.1 for conducting the common circuits FU2.1 and FU2.2 to the operating voltage VDD2. The switches S6.1 and S6.2 of the switch circuits FU4.1 and FU4.2 do not conduct, and the control end a1 of each common circuit is conducted via the switch S6.3 to the predetermined voltage source V1 as a control signal. By the control signal, the common circuits FU2.1 and FU2.2 are controlled to conduct, which means transistor Mp is conducted between source and drain which has a conductive resistance therebetween; that is, an equivalent termination resistor is provided at each common end a2 of the common circuits FU2.1 and FU2.2.

In such a mode, the input signals 12M and 12P are a pair of differential rejection signals. The driving circuits FU3.1 and FU3.2 determine whether to conduct the output ends b2 to the coupling circuit FU5 according to the input signals 12M and 12P at the input ends b1. Only one of the driving circuit pair FU3.1 and FU3.2 conducts. Accordingly, this configuration allows the signal transmitter conforming to the current logic interface specification. For example, when the transistor Mn3.3 of the driving circuit FU3.2 is conducted by the input signal 12P, the N2P conducts to approximate the operating voltage GND, so that the output signal OUTP is logical-low. In contrast, when the transistor Mn3.3 of the driving circuit FU3.1 does not conduct, and under operations of the common circuit FU2.1, a voltage at the node N2M approximates the operating voltage VDD2, so that the output signal OUTM is logical-high. That is, the output signals OUTP and OUTM are differential signals to each other, and the output transmitter 10 operates as a dual-end differential output circuit.

FIG. 9 shows a schematic diagram of the output transmitter 10 operating in a third transmission mode in accordance with an embodiment of the present invention, shown by the same components in the previous embodiments, such as the common circuit B4.1 in FIG. 3, the driving circuit B5.2 in FIG. 4, and the switch circuit B6.1 in FIG. 5. When the output transmitter 10 operates in this mode (e.g., a mode supporting common purpose output), the coupling circuits FU1 and FU5 are seen as resistors R0 and R1, as shown in the FIG. 9, and are equivalent to the coupling circuit B3.3 in FIG. 2 and the coupling circuit B7.2 in FIG. 6. Operations of the switch circuits FU4.1 and FU4.2 are similar to those in FIG. 7. More specifically, the switch S6.1 conducts, and the switches S6.2 and S6.3 do not conduct, so that the control ends a1 of the common circuits FU2.1 and FU2.2 are respectively coupled to the input signals I1P and I1M. In this mode, the input signals I1M and I2M are in-phase signals, and the input signals I1P and I2P are another pair of in-phase signals, where the signal pairs I1M/I2M and I1P/I2P can be independent and irrelative, so that the common circuit FU2.1 and the driving circuit FU3.1 form a single-end output circuit, while the common circuit FU2.2 and FU3.2 form another single-end output circuit independent from the former one. That is, in the transmission mode of this embodiment, through driving of the driving circuit and the common circuit, the two output signals OUTM and OUTP are two independent single-end signals instead of differential signals as described in the previous embodiments. In other words, the output transmitter 10 provided in this embodiment operates as two independent single-end output circuits. In each single-end output circuit, the common circuit realizes a drive high/pull-up driver, and the corresponding driving circuit realizes a drive low/pull-down driver. For example, for the single-end output circuit formed by the common circuit FU2.1 and the driving circuit FU3.1, when the transistor Mp of the common circuit FU2.1 is conducted by the input signal I1M, the transistor Mn3.3 of the driving circuit FU3.1 does not conduct so that the common circuit FU2.1 raises the voltage level of the output signal OUTM at the node N2M to approximate the logical-high operating voltage VDD2. In contrast, when the transistor Mp of the common circuit FU2.1 does not conduct, the transistor Mn3.3 of the driving circuit FU3.1 conducts to lower the output signal OUTM at the node N2M to approximate the logical-low operating voltage GND.

The common circuits B4.2 and B4.6 in FIG. 3 illustrate five embodiments of the common circuits FU2.1 and FU2.2. The common circuit B4.2 further comprises a resistor R in addition to the transistor Mp of the common circuit B4.1. The resistor R has one end coupled to the drain of the transistor Mp at a node Na1, and another end as the common end a2 of the common circuit B4.2. When the output transmitter 10 operates in the second transmission mode, and the transistor Mp of the common circuit B4.2 conducts, the resistor R is connected in serial to a source-drain conductive resistor of the transistor Mp to provide a termination resistor. The resistor R can improve linearity (e.g., a linearity of a relationship between current and voltage) of the termination resistor.

In another embodiment, the common circuit B4.3 further comprises a transistor Mn in addition to the transistor Mp and the resistor R of the common circuit B4.2. The transistor Mn is an n-channel MOSFET, which has a drain and a source respectively coupled to the drain or the source of the transistor Mp, and a gate having a bias voltage V3 (such as the operating voltage VDD2). When the output transmitter 10 operates in the second transmission mode, the voltage V3 conducts the transistor Mn to operate in a configuration similar to a transmission gate together with the transistor Mp. Under such a configuration, source-drain conductive resistors of the transistor Mp and that of the transistor Mn are connected in parallel between nodes Na1 and Na2, and then the paralleled resistance is in serial to the resistor R to work as a termination resistor. The parallel resistor provided by the transistor Mn is capable of reducing an equivalent resistance between the nodes Na1 and Na2, so that linearity of the termination resistor is improved.

In other embodiments of the common circuits FU2.1/FU2.2, the common circuits B4.4, B4.5 and B4.6 are respectively derived from the common circuits B4.1, B4.2 and B4.3, and principles of operation of those common circuits are similar. However, in the common circuits B4.4 to B4.6, the transistor Mp is a floating n-well p-channel MOSFET, i.e., the transistor Mp has a floating bulk. To operate with such type of transistor, the common circuits B4.4 to B4.6 dispose a control circuit CTR coupled between a gate and a drain of the transistor Mp to adjust a gate voltage according to a drain voltage of the transistor Mp. For example, when the operating voltage VDD2 of the output transmitter 10 terminates, the control circuit CTR is able to reduce a voltage difference between the gate and the drain to reduce a leakage current of the transistor Mp, such as the leakage current drained to the common end a2 from the output end b2 (in FIG. 1). In certain interface specifications, currents drained by an output transmitter from external circuits are defined/limited with respect to situations that an operating voltage of the output transmitter terminates. The foregoing floating n-well configuration facilitates the output transmitter 10 to adapt to various types of specifications.

The driving circuit B5.1 in FIG. 4 illustrates the driving circuit FU3.1/FU 3.2 in accordance with another embodiment of the present invention. In the driving circuit B5.1, functions and operations of a transistor Mn3.2 are similar to those of the transistor Mn3.3 of the driving circuit B5.2. The transistor Mn3.2 is also an n-channel MOSFET, which has a gate coupled to the input end b1 to determine whether to conduct between its drain and source according to the signal at the input end b1. In addition, the driving circuit B5.1 comprises a second transistor Mn3.1 and a feedback circuit FC. The transistor Mn3.1 is an n-channel MOSFET, which has a source and a drain respectively coupled to the drain of the transistor Mn3.2 at node Nb1 and coupled to the output end b2 of the driving circuit B5.1 at node Nb2. The feedback circuit FC is coupled between nodes Nb2 and Nb3 to correspondingly adjusting a gate voltage of the transistor Mn3.1 according to a voltage signal at the output end b2 (i.e., the node Nb2). For example, in an embodiment, when the voltage at the output end b2 is overly-high, the feedback circuit FC provides a lower voltage to the node Nb3 to reduce a drain voltage of the transistor Mn3.2 via a gate-source voltage of the transistor Mn3.1 and protect the transistor Mn3.2 from over voltage at the output end b2. In other words, the transistor Mn3.1 is regarded as an over-voltage protector of the transistor Mn3.2. Therefore, the transistor Mn3.2 can be realized by a thin oxide layer transistor to reduce area configuration as well as power consumption of the pre-driver B2.3. The transistors Mn3.1 and Mn3.3 in FIG. 4 may also be a thick oxide layer transistor.

In another situation, when the voltage at the output end b2 is overly-low, the feedback circuit FC provides a higher voltage to the node Nb3. Accordingly, the higher voltage appropriately increases the voltage at the node Nb1 via the gate-drain voltage of the transistor Mn3.1 to avoid entering a triode region due to the over-low drain voltage of the transistor Mn3.2. In short, through operations of the feedback circuit FC, the transistor Mn3.1 increases conductive level and driving capabilities of the transistor Mn3.2.

The I/O operating voltage VDD2 for operating the output transmitter 10 in FIG. 1 is larger than, equal to, or smaller than the core operating voltage VDD1. In applications where the operating voltage VDD2 is equal to or smaller than the operating voltage VDD1, the designs of feedback circuit FC/the transistor Mn3.1 of the driving circuit B5.1 in FIG. 4 and the transistor Mn of the common circuit B4.3/B4.6 in FIG. 3 facilitate the output transmitter 10 in a low I/O operating voltage VDD2. The feedback circuit FC/the transistor Mn3.1 avoids the driving circuit B5.1 operating in error operation regions (e.g., the triode region) under the situation of low operating voltage. The low I/O operating voltage VDD2 reduces conductive degrees of the transistor Mp of the common circuit FU2.1/2.2 to adjust the termination resistor, and accordingly the transistor Mn of the common circuit B4.3/B4.6 is appropriately improved.

With respect to different combinations of “larger than, smaller than, or equal to” of the operating voltage VDD1/VDD2, the switch S6.3 of the switch circuit B6.1 in FIG. 5 facilitates the output transmitter 10 to correctly enter a power-saving mode, in which the common circuit FU2.1/FU2.2 and the driving circuit FU3.1/FU3.2 of the output transmitter 10 are completely turned off. The pre-driver B2.3 in FIG. 1 transmits the operating voltage GND to the input end b1 of the driving circuit FU3.1/FU3.2 to turn off the driving circuit FU3.1/FU3.2. In applications that the operating voltage VDD1 is larger than the operating voltage VDD2, since the pre-driver B2.2 operates in the low operating voltage VDD1, in the event that the pre-driver B2.2 directly provides the operating voltage VDD1 to the control end a1 of the common circuit FU2.1/FU2.2, the common circuit FU2.1/FU2.2 operating in the high operating voltage cannot be completely turned off. Therefore, in the applications that the operating voltage VDD1 is smaller than the operating voltage VDD2, the control end a1 of the common circuit FU2.1/FU2.2 is conducted to a high predetermined voltage V1, which is greater than the operating voltage VDD1, via the switch S6.3 of the switch circuit B6.1 (the switches S6.1 and S6.2 do not conduct), so as to completely turn off the common circuit FU2.1/FU2.2. For example, the voltage V1 is equal to the voltage VDD2. In applications where the operating voltage VDD1 is greater than or equal to operating voltage VDD2, the switch circuit B6.1 conducts the switch S6.1 (the switches S6.2 and S6.3 are turned off) to provide via the pre-driver B2.2 an appropriate voltage to the control end a1, so as to turn off the common circuit FU2.1/FU2.2.

In conclusion, compared to the prior art, the common circuits FU2.1/FU2.2 of the output transmitter 10 are enabled to conduct to perform in different transmission modes. The output transmitter 10 is widely adapted to various applications where the operating voltage VDD1 is larger than, equal to, or smaller than the operating voltage VDD2. The feedback circuit FC of the driving circuit B5.1 in FIG. 4 is capable of controlling the transistor MN3.1 according to the signal voltage situation at the output end a2 thereby facilitating operations of the transistor MN3.2. The common circuits B4.4 to B4.6 in FIG. 3 may be realized by the floating n-well configuration and the control circuit CTR. to more appropriately adapt to requirements of various types of interface specifications.

While the invention has been described in terms of what is presently considered to be the most practical and preferred embodiments, it is to be understood that the invention needs not to be limited to the above embodiments. On the contrary, it is intended to cover various modifications and similar arrangements included within the spirit and scope of the appended claims which are to be accorded with the broadest interpretation so as to encompass all such modifications and similar structures.

What is claimed is:

1. An output transmitter, comprising:
a pair of driving circuits; and
a pair of common circuits, coupled to the pair of driving circuits;
wherein, when the output transmitter operates in a first transmission mode, conduction of each of the common circuits is dependent on an input signal, and when the output transmitter operates in a second transmission mode, each of the common circuits forms a termination resistor according to a control signal.

2. The output transmitter as claimed in claim 1, wherein:
each of the driving circuits has a driving input end and a driving output end; and
each of the common circuits has a control end and a common end, each of the common ends is coupled to the driving output end;
wherein, when the output transmitter operates in the first transmission mode, the control end and the common end conduct to generate a driving current, and when the output transmitter operates in the second transmission mode, the termination resistor is generated between the control end and the common end.

3. The output transmitter as claimed in clam 2, further comprising:
a switch circuit, coupled to at least one of the common circuits;
wherein, when the output transmitter operates in the first transmission mode, the switch circuit conducts current input to the switch circuit to the control end of at least one common circuit, and when the output transmitter operates in the second transmission mode, the switch circuit conducts to a predetermined voltage to provide the control signal to at least one common circuit.

4. The output transmitter as claimed in claim 3, wherein the switch circuit further comprises:
a switch input end;
a coupling end, coupled to one of the control ends of the common circuits;
a first switch, coupled between the switch input end and the coupling end, for conducting the incoming current in the first transmission mode; and
a second switch, coupled between the predetermined voltage and the coupling end, for conducting the predetermined voltage in the second transmission mode.

5. The output transmitter as claimed in claim 4, wherein the switch circuit further comprises:
a third switch, coupled between a second predetermined voltage and the coupling end, for conducting in a power-saving mode.

6. The output transmitter as claimed in claim 4, wherein a pair of switch circuits are coupled to the control ends of the pair of common circuits, and when the output transmitter operates in the first transmission mode, the switch circuits respectively receive a pair of rejection signals that are transmitted to the control ends of the common circuits.

7. The output transmitter as claimed in claim 2, wherein each driving circuit comprises an n-channel metal-oxide-semiconductor field-effect transistor (MOSFET), having a gate coupled to the driving input end, and a drain coupled to the driving output end.

8. The output transmitter as claimed in claim 7, wherein each of the driving circuits further comprises:
a second transistor, having a first end, a second end, and a third end, wherein the second end and the third end are respectively coupled to the n-channel MOSFET and the driving output end; and
a feedback circuit, coupled between the first end and the third end, for adjusting a voltage at the first end according to a signal at the third end.

9. The output transmitter as claimed in claim 2, wherein each of the common circuits comprises a p-channel MOSFET, which has a gate coupled to the control end, and a drain coupled to the common end.

10. The output transmitter as claimed in claim 9, wherein each of the common circuits further comprises a resistor coupled between the drain of the p-channel MOSFET and the common end.

11. The output transmitter as claimed in claim 10, wherein each of the common circuits further comprises an n-channel MOSFET, which has a drain and a source respectively coupled to one of the drain and the source of the p-channel MOSFET.

12. The output transmitter as claimed in claim 9, wherein the p-channel MOSFET is a floating n-well p-channel MOSFET, and each of the common circuits further comprises:
a control circuit, coupled between the gate and the drain of the p-channel MOSFET.

13. The output transmitter as claimed in claim 1, further comprising:
a coupling circuit, coupled to the common circuits;
wherein, when the output transmitter operates in the first operating mode, the coupling circuit provides a current to the common circuits, and when the output transmitter operates in the second operating mode, the coupling circuit conducts the common circuits to an operating voltage.

14. The output transmitter as claimed in claim 1, further comprising:
a coupling circuit, coupled to the driving circuits, for selectively providing a current to the driving circuits.

15. The output transmitter as claimed in claim 1, wherein when the output transmitter operates in a third transmission mode, the common circuits conducting current dependent on a plurality of input signals, respectively, and the plurality of input signals are independent from each other.
